(19) United States
(12) Patent Application Publication
(10) Pub. No.: US 2005/0219827 A1
(43) Pub. Date: Oct. 6, 2005

(54) Electrical circuit device

(75) Inventors: Osamu Tateyama, Kariya-city (JP); Takeyoshi Hisada, Hekinan-city (JP); Koichi Sato, Anjo-city (JP); Akira Sugiura, Okazaki-city (JP); Koichi Tsukada, Okazaki-city (JP)

Correspondence Address: POSZ LAW GROUP, PLC, 12040 SOUTH LAKES DRIVE, SUITE 101, RESTON, VA, 20191, US

(73) Assignees: ANDEN CO., LTD.; DENSO CORPORATION

(21) Appl. No.: 11/091,422

(22) Filed: Mar. 29, 2005

(30) Foreign Application Priority Data
Mar. 31, 2004 (JP) 2004-104846

(51) Int. Cl. H05K 1/14

(52) U.S. Cl. 361/736; 307/143

(57) ABSTRACT

An electrical circuit device includes a controller, drivers, and a case. The controller inputs driving signals to the drivers. The drivers have multiple semiconductor relays that turn on and off power supply to electrical loads based on the driving signals. The drivers are housed in the case. The driving signals are transmitted from the controller to the drivers via serial communication. With this configuration, the number of communication lines and the communication connectors and the size of the electrical circuit device are small with respect to parallel communication. When another driver is added, only software modification of the controller and addition of a serial communication line between the controller and the driver are required. Thus, the electrical circuit device can be easily modified for different models of vehicles.

### CROSS REFERENCE TO RELATED APPLICATION

This application is based on and incorporates herein by reference Japanese Patent Application No. 2004-104846 filed on Mar. 31, 2004.

### FIELD OF THE INVENTION

The present invention relates to an electrical circuit device having semiconductor relays for turning on and off power supply to an electrical load.

### BACKGROUND OF THE INVENTION

An electrical circuit device having a driver in which multiple semiconductor relays and electrical components are surface-mounted on a single surface of a circuit board is proposed in JP-A-2003-164039. Driving signals for controlling the semiconductor relays are inputted into the electrical circuit device from an external control unit through parallel communication.

The electrical circuit device requires a number of communication lines and communication connector terminals since it uses the parallel communication. As a result, the electrical circuit device is large in size. Moreover, a large number of additional communication lines and connector terminals are required in addition to modifications to software when the electrical circuit device is installed in a vehicle and drives for electrical load of the vehicle are added. Thus, modifying the electrical circuit device for different models of vehicles is not easy.

A large number of the semiconductor relays are surface-mounted on a single surface of the circuit board in the electrical circuit device. Therefore, a mounting surface of the circuit board requires a large area.

### SUMMARY OF THE INVENTION

The present invention therefore has an objective to provide a small size electrical circuit device that is easily modified for different application. An electrical circuit device of the present invention includes a controller, drivers, and a case. The controller inputs driving signals to the drivers. The drivers have multiple semiconductor relays that turn on and off power supply to electrical loads based on the driving signals. The drivers are housed in the case.

The driving signals are transmitted from the controller to the drivers via serial communication. With this configuration, the number of communication lines and the communication connectors and the size of the electrical circuit device are small with respect to parallel communication. When another driver is added, only software modification of the controller and addition of a serial communication line between the controller and the driver are required. Thus, the electrical circuit device can be easily modified for different models of vehicles.

### BRIEF DESCRIPTION OF THE DRAWINGS

The above and other objectives, features and advantages of the present invention will become more apparent from the following detailed description made with reference to the accompanying drawings. In the drawings:

FIG. 1 is a perspective view of an electrical circuit device according to the first embodiment of the present invention;

FIG. 2 is a cross-sectional view of the electrical circuit device according to the first embodiment;

FIG. 3 is a bottom view of a case of the electrical circuit device according to the first embodiment;

FIG. 4 is a circuit diagram of an equivalent circuit of the electrical circuit device according to the first embodiment; and

FIG. 5 is a cross-sectional view of an electrical circuit device according to the second embodiment.

### DETAILED DESCRIPTION OF THE PREFERRED EMBODIMENT

The preferred embodiments of the present invention will be explained with reference to the accompanying drawings. In the drawings, the same numerals are used for the same components and devices.

[First Embodiment]

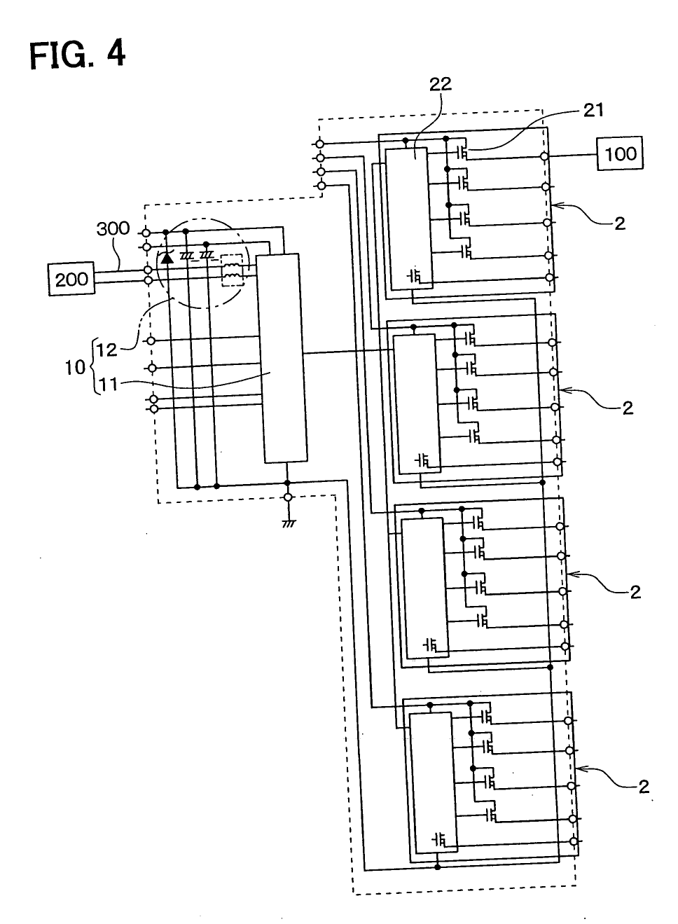

Referring to FIG. 4, an electrical circuit device 1 is connected for controlling on and off of electrical loads 100 of a vehicle, including lamps and motors. An electronic control unit (ECU) 200 determines whether power supply to the electrical loads 100 is necessary, and signal indicating results of the determination is transmitted from the ECU 200 to a controller 10 of the electrical circuit device 1 via serial communication. A serial communication line 300 is connected between the ECU 200 and the controller 10.

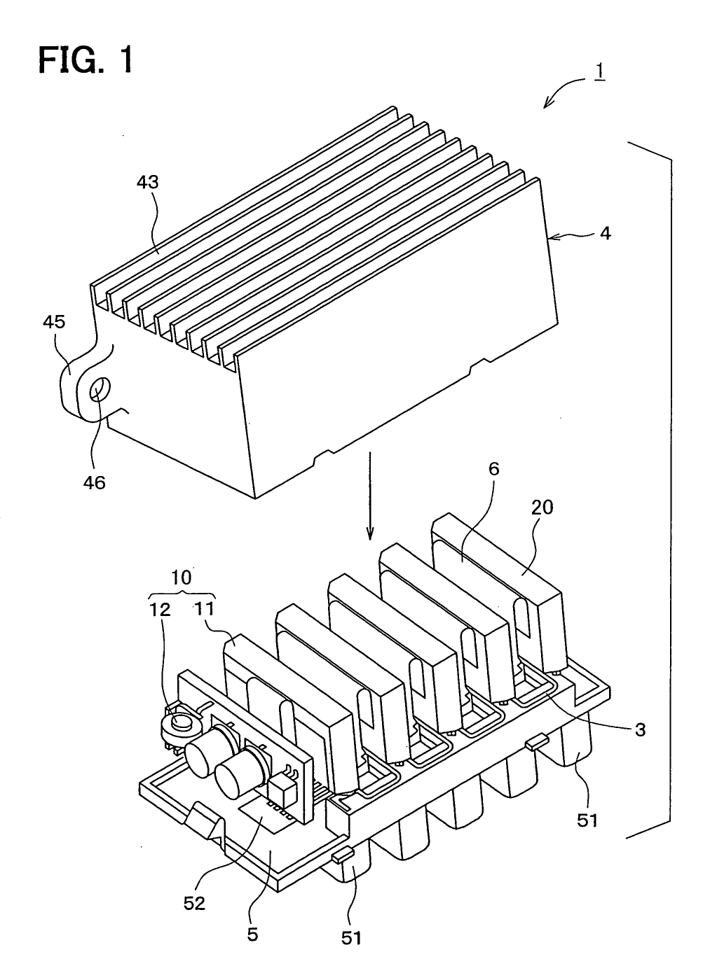

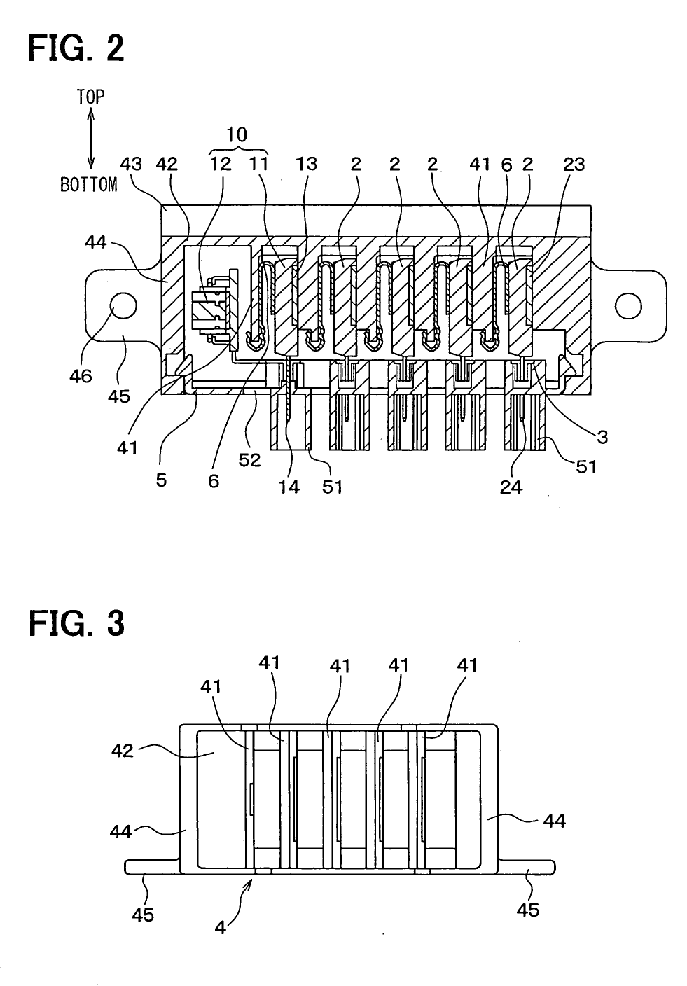

Referring to FIGS. 1 through 3, an electrical circuit device 1 includes the controller 10, four drivers 20, bus bars 3, and a case 4. The controller 10 inputs driving signals to the drivers 20 based on power supply on/off signals from an ECU 200. The driving signals are on/off signals for semiconductor relays 21 included in the drivers 20, and transmitted from the controller 10 to the drivers 20 via serial communication. Each driver 20 includes the semiconductor relays 21, a relay controller 22, and peripheral circuits (not shown) that form a semiconductor driver together with the semiconductor relays 21.

The case 4 is made of aluminum and formed in a rectangular parallelepiped with space inside and an opening at the bottom. The case 4 has partition walls 41 for dividing its interior space into multiple subsections. The partition walls 41 extend from the inner surface of a top wall 42 toward the bottom. The partition walls are arranged horizontally parallel to each other. The controller 10 and the drivers 20 are arranged in respective subsections divided with the partition walls 41.

A number of radiating fins 43 are formed on the outer surface of the top wall 42. Flaps 45 are formed on side wall 44 of the case 4, one for each side wall 44. Each flap 45 has a through-hole 46 through which a mounting screw (not shown) is inserted. The opening of the case 4 is covered with a resin cover 5. Connector housing portions 51 are formed on an outer surface of the cover 5 and the bus bars 3 are fixed to the cover 5. The cover 5 has continuous holes 52 through which clips 6 are passed for establishing communication between the interior space and the external space of the case 4.

The controller 10 has two parts: a thin box shaped main unit 11 and a sub unit 12 including large heat-producing components, such as a capacitor. The main unit 11 has a microcomputer (not shown) that processes the signal from the ECU 200 as a main unit. The microcomputer and peripheral circuits are housed in a molded resin case. The main unit 11 includes a radiating plate 13 that is exposed at the surface of the molded resin case. The main unit 11 is held in the subsection such that the radiating plate 13 is pressed against the partition wall 41 with the clip 6 that is a flat spring having spring tension provided as a holding member. Heat produced inside the main unit 11 is released to the outside via the radiating plate 13, the partition wall 41, and the radiating fins 43.

Lead terminals 14 are connected with a lead frame of the main unit 11. Two of the lead terminals 14 for the serial communication line and a ground are partly inserted in a terminal insertion portion of the bus bar 3. As a result, the main unit 11 is electrically connected with the bus bar 3. Other lead terminals extend to inner space of the connector housing portion 51. The other terminals form a connecter for connecting the main unit 11 to an external device.

The sub unit 12 includes a bus bar circuit board in which bus bars 3 are assembled with molded resin by insert molding. Electrical components are mounted on the busbar circuit board. Lead terminals of the sub unit 12 are welded to the lead terminals 14 of the main unit 11.

Each driver 20 has a thin box-shaped molded resin case. The semiconductor relays 21, the relay controller 22, and the peripheral circuits are housed in the resin case. The driver 20 includes a radiating plate 23 that is exposed at the surface of the resin case. The driver 20 is held in the subsection such that the radiating plate 23 is pressed against the partition wall 41 with the clip 6. Heat produced inside the driver 20 is released to the outside via the radiating plate 23, the partition wall 41, and the radiating fins 43.

Lead terminals 24 are connected with a lead frame of each driver 20. Two of the lead terminals 24 for the serial communication line between the main unit 11 and the driver 20, or between the drivers 20, and a ground are partly inserted in a terminal insertion portion of the bus bar 3. As a result, the driver 20 is electrically connected with the bus bar 3. Other lead terminals extend to inner space of the connector housing portion 51. The other terminals form a connecter for connecting the driver 20 to an external device.

The lead terminals 14 of the main unit and the lead terminals 24 of the drivers 20 are inserted in the insertion portions of the bus bar 3. Thus, the driving signals are transmitted from the controller 10 to each driver 20 via serial communication, namely, the bus bars 3 are serial communication line for driving signal transmission. Moreover, the controller 10 and the drivers 20 are connected to the ground via the bus bars 3. The main unit 11 and the drivers 20 are arranged such as shelves as shown in FIG. 1 when the longitudinal direction of the electrical circuit device 1 is aligned to the vertical direction.

With this configuration, the signals indicating results of the power supply necessity determination and the driving signals are transmitted from the ECU 200 to the controller 10 via serial communication. As a result, the number of communication lines and the communication connectors and the size of the electrical circuit device 1 are small with respect to parallel communication.

When another driver 20 is added, only software modification of the controller 10 and addition of a serial communication line between the controller 10 and the driver 20 are required. Thus, the electrical circuit device 1 can be easily modified for different models of vehicles.

The case 4 and the radiating fins 43 are integrated and therefore a connecting member is not required for connecting the radiating fins 43 to the case 4, which enables a size reduction in the electrical circuit device 1. The shelf-like arrangement of the main unit 11 and the drivers 20 enables a large size reduction in the top-view area of the electrical circuit device 1. The size reduction in the top-view area is important for saving mounting space in a vehicle.

The controller 10 is installed separately from the drivers 20. Heat produced in the controller 10 and in the drivers 20 is dispersed. Thus, the heat is efficiently released with small radiating fins 43. The size reduction in the radiating fins 43 enables a size reduction in the electrical circuit device 1. The main unit 11 and the drivers 20 are pressed against the partition walls 41 and therefore the heat is efficiently released with small radiating fins 43. The size reduction in the radiating fins 43 enables a size reduction in the electrical circuit device 1.

The lead terminals 14, 24 function as connector terminals. Therefore, the number of parts and the mounting space are small with respect to the case that the connector terminals are separately provided.

The controller 10 and the drivers 20 can be mounted on a printed circuit board. They can be connected with each other via connecting members other than the bus bars 3, such as patterns on the printed circuit board and wire harnesses.

[Second Embodiment]

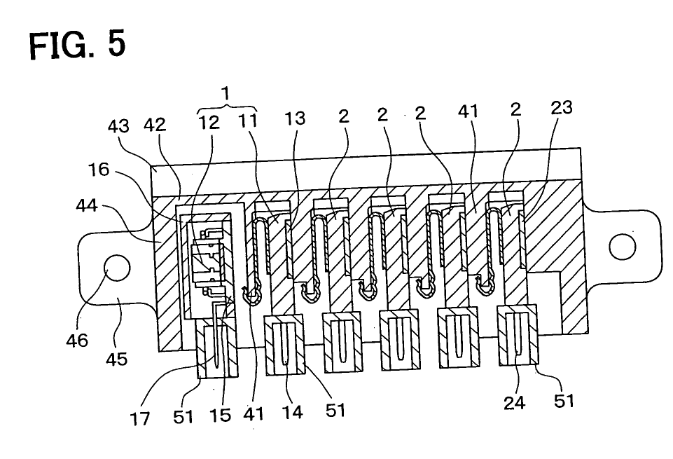

Referring to FIG. 5, the connector housing portions 51 are integrally formed with the main unit 11 and the drivers 20. The bus bars 3 and the cover 5 of the first embodiment are not provided.

A bus bar 15 is exclusively provided for the sub unit 12 and the electrical components are mounted on the bus bar 15. The components are housed in a resin case 16 and the connector housing case 51 is integrated to the sub unit 12. Connector terminals 17 are connected to the bus bar 15. The connector terminals 17 extend to inner space of the connector housing portion 51. The sub unit 12 is fixed to the case 4 by engaging the case 16 in the case 4. The main unit 11, the sub unit 12, and the drivers 20 are electrically connected with each other via wire harnesses of external connectors (not shown) attached to the connector housing portion 51.

The present invention should not be limited to the embodiment previously discussed and shown in the figures, but may be implemented in various ways without departing from the spirit of the invention. For example, the connector housing portions 51 can be integrally formed with the main unit 11, the sub unit 12, and the drivers 20. Alternatively, the connector housing portions 51 can be separately prepared and fixed to the main unit 11, the sub unit 12, and the drivers 20.

1. An electrical circuit device comprising:
drivers having plurality of semiconductor relays for turning on and off power supply to an external electrical load based on driving signals;
a controller that produces the driving signals and inputs the driving signals to the driver;
a case that houses the drivers; and
a serial communication line connected between the controller and the drivers, wherein the driving signals are transmitted from the controller to the drivers via the serial communication line.

2. The electrical circuit device according to claim 1, wherein the case includes radiating fins.

3. The electrical circuit device according to claim 1, wherein:
the case has a plurality of partition walls for dividing inner space thereof into a plurality of subsections;
the partition walls are arranged parallel to each other; and
the drivers are arranged in the respective subsections.

4. The electrical circuit device according to claim 3, further including holding members having spring tension, wherein the drives are pressed against the partition walls with the holding members.

5. The electrical circuit device according to claim 1, wherein:
the drivers include lead terminals; and
the lead terminals are configured to be connectable to an external device.

6. The electrical circuit device according to claim 1, further comprising a serial communication line that is connectable to an external device, wherein:
the serial communication line is connected to the controller; and
the controller receives signals from the external device via the communication line.

7. The electrical circuit device according to claim 6, wherein the signals received by the controller are pertaining to whether power supply is necessary for the electrical load.

8. The electrical circuit device according to claim 1, wherein the controller is housed in the case.

9. The electrical circuit device according to claim 8, wherein the serial communication line is implemented via a bus bar.

10. The electrical circuit device according to claim 8, wherein the controller is constructed of multiple units.
